(19) United States
(12) Patent Application Publication
(10) Pub. No.: US 2025/0374564 A1
(43) Pub. Date: Dec. 4, 2025

(54) SEMICONDUCTOR DEVICE AND METHODS FOR FORMING THE SAME

(71) Applicant: YANGTZE MEMORY TECHNOLOGIES CO., LTD., Wuhan (CN)

(72) Inventors: Hao Zhang, Wuhan (CN); Zhaoyun Tang, Wuhan (CN); Wenyu Hua, Wuhan (CN)

(21) Appl. No.: 18/752,627

(22) Filed: Jun. 24, 2024

(30) Foreign Application Priority Data
May 28, 2024 (CN) 202410675135.1

(51) Int. Cl. H01L 27/06; H01L 29/78; H10B 12/00

(52) U.S. Cl. CPC H10D 1/042; H10B 12/033; H10D 1/716; H10D 30/63; H10D 84/811

(57) ABSTRACT

A semiconductor device and method for forming thereof are provided. The semiconductor device includes transistors and capacitors coupled with the transistors, respectively. Each capacitor includes a first electrode extending along a vertical direction and coupled with a corresponding transistor, a dielectric layer laterally surrounding the first electrode, and a second electrode laterally surrounding the dielectric layer. The dielectric layer includes at least one step-shaped shift along the vertical direction and a diameter difference between a first diameter of the dielectric layer at a first side of the step-shaped shift and a second diameter of the dielectric layer at a second side of the step-shaped shift.

### CROSS-REFERENCE TO RELATED APPLICATIONS

This application claims the benefit of priority to Chinese Application No. 202410675135.1, filed on May 28, 2024, which is incorporated herein by reference in its entirety.

### BACKGROUND

The present disclosure relates to semiconductor devices and methods for forming thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

### SUMMARY

In one aspect, a semiconductor device including transistors and capacitors coupled with the transistors respectively is provided. Each capacitor includes a first electrode extending along a vertical direction and coupled with a corresponding transistor, a dielectric layer laterally surrounding the first electrode, and a second electrode laterally surrounding the dielectric layer. The dielectric layer includes at least one step-shaped shift along the vertical direction and a diameter difference between a first diameter of the dielectric layer at a first side of the step-shaped shift and a second diameter of the dielectric layer at a second side of the step-shaped shift.

In some implementations, the dielectric layer includes a first step-shaped shift and a second step-shaped shift continuously connected with each other and lifted toward opposite directions along the vertical direction.

In some implementations, the first step-shaped shift and the second step-shaped shift share a common step surface positioned at a middle portion of the dielectric layer along the vertical direction.

In some implementations, the dielectric layer includes a third step-shaped shift at a bottom of the dielectric layer along the vertical direction, and the dielectric layer has an L-shaped cross section at the bottom of the dielectric layer.

In some implementations, the first electrode includes a vertical body with at least one recess around the vertical body, and the at least one recess corresponds to the at least one step-shaped shift of the dielectric layer. A diameter of the recess is smaller than a diameter of the vertical body.

In some implementations, the first electrode has an L-shaped cross section at a bottom of the first electrode.

In some implementations, the first electrode includes a first barrel layer having a same shape as the dielectric layer and a vertical core filled in a cavity of the first barrel layer. A material of the first barrel layer is different from a material of the vertical core.

In some implementations, the second electrode includes a vertical cavity with at least one protrusion around the vertical cavity, and the at least one protrusion corresponds to the at least one step-shaped shift of the dielectric layer. A diameter of the protrusion is smaller than a diameter of the vertical cavity.

In some implementations, the second electrode has an L-shaped cross section at a bottom of the second electrode.

In some implementations, the second electrode includes a second barrel layer having a same shape as the dielectric layer and a parcel layer surrounding the second barrel layer. A material of the second barrel layer is different from a material of the parcel layer.

In some implementations, a height of the first electrode is larger than a height of the second electrode along the vertical direction.

In some implementations, the capacitors are arranged in a grid array in which four adjacent capacitors are located at four corners of a rectangle, respectively.

In some implementations, two second electrodes of two capacitors located at two adjacent corners of each rectangle in the grid array are in contact with each other.

In some implementations, a space between the four adjacent capacitors located at four corners of a rectangle is filled by the second electrode of the four adjacent capacitors.

In some implementations, the first electrode of each capacitor is coupled with a source of the corresponding transistor through a source node contact.

In another aspect, a method for forming a semiconductor device is provided. The method includes forming a second electrode of a capacitor along a vertical direction, forming a dielectric layer of the capacitor laterally surrounded by the second electrode, forming at least one step-shaped shift on the dielectric layer along the vertical direction, wherein a first diameter of the dielectric layer at a first side of the step-shaped shift is different with a second diameter of the dielectric layer at a second side of the step-shaped shift, and forming a first electrode laterally surrounded by the dielectric layer.

In some implementations, forming the second electrode includes forming an isolation layer on a transistor, forming a hole in the isolation layer along a vertical direction, and forming the second electrode covering an inner surface of the hole.

In some implementations, the isolation layer includes a multiple-layer structure including at least one mesh layer and at least one sacrificial layer stacked alternatively and a top layer and a bottom layer of the multiple-layer structure are mesh layers.

In some implementations, a material of the at least one mesh layer, a material of the at least one sacrificial layer, and a material of the dielectric layer are different from each other.

In some implementations, forming a hole in the isolation layer includes etching each sacrificial layer to form a corresponding recession along a lateral direction. An adjacent mesh layer protrudes into the hole with respect to the sacrificial layer. At least one initial step-shaped shift is formed between a mesh layer and an adjacent sacrificial layer at an edge of each recession.

In some implementations, forming a second electrode in the hole includes forming a second barrel layer covering a side surface of the hole and etching part of the second barrel layer to expose a vertical surface of each mesh layer and a bottom of the hole.

In some implementations, forming the dielectric layer and forming the at least one step-shaped shift on the dielectric layer includes forming the dielectric layer covering an inner surface of the second barrel layer, the vertical surface of each mesh layer, and the bottom of the hole, and forming at least one step-shaped shift corresponding to the at least one initial step-shaped shift.

In some implementations, forming the first electrode includes forming a first barrel layer covering the dielectric layer.

In some implementations, forming the first electrode further includes forming a through hole penetrating the dielectric layer and the first barrel layer on the bottom of the hole to expose the transistor under the capacitor. A diameter of the through hole is smaller than an inner diameter of the first barrel layer.

In some implementations, forming the first electrode further includes forming a vertical core filled in a cavity of the first barrel layer and the through hole to couple the first electrode with the transistor. A material of the vertical core is different from a material of the first barrel layer.

In some implementations, forming the second electrode further includes replacing the at least one sacrificial layer and the at least one mesh layer with a parcel layer. A material of the parcel layer is different from a material of the second barrel layer.

In some implementations, the semiconductor device includes a plurality of capacitors. The method further includes forming a plurality of transistors corresponding to the plurality of capacitors. The capacitors are arranged in a grid array in which four adjacent capacitors are located at four corners of a rectangle, respectively.

In yet another aspect, a semiconductor device including a plurality of capacitors is provided. The capacitors are arranged in a grid array in which four adjacent capacitors are located at four corners of a rectangle, respectively. Each of the capacitors includes a first electrode extending along a vertical direction and coupled with a corresponding transistor, a dielectric layer laterally surrounding the first electrode, and a second electrode laterally surrounding the dielectric layer. The dielectric layer of each electrode has an L-shaped cross section at a bottom of the dielectric layer.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells each having a vertical transistor, according to some implementations of the present disclosure.

FIGS. 2A-2D each illustrates schematic views of a semiconductor device at a certain stage of a fabricating method, according to various implementations of the present disclosure.

FIG. 3A illustrates a schematic side view of a cross-section of a semiconductor device with vertical transistors and storage units of the semiconductor device, according to some implementations of the present disclosure.

FIG. 3B is an enlarged view of region A in FIG. 3A.

FIG. 3C is an enlarged view of region B in FIG. 3A.

FIG. 4 illustrates a flowchart of a fabricating method for forming the semiconductor device, according to some implementations of the present disclosure.

FIGS. 5A-12C each illustrates schematic views of the semiconductor device at a certain fabricating stage of the method shown in FIG. 4, according to various implementations of the present disclosure.

FIG. 13A illustrates a vertical cross section of a dielectric layer of the semiconductor device in FIG. 12C.

FIG. 13B illustrates a vertical cross section of a first electrode of the semiconductor device in FIG. 12C.

FIG. 13C illustrates a vertical cross section of a second electrode of the semiconductor device in FIG. 12C.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

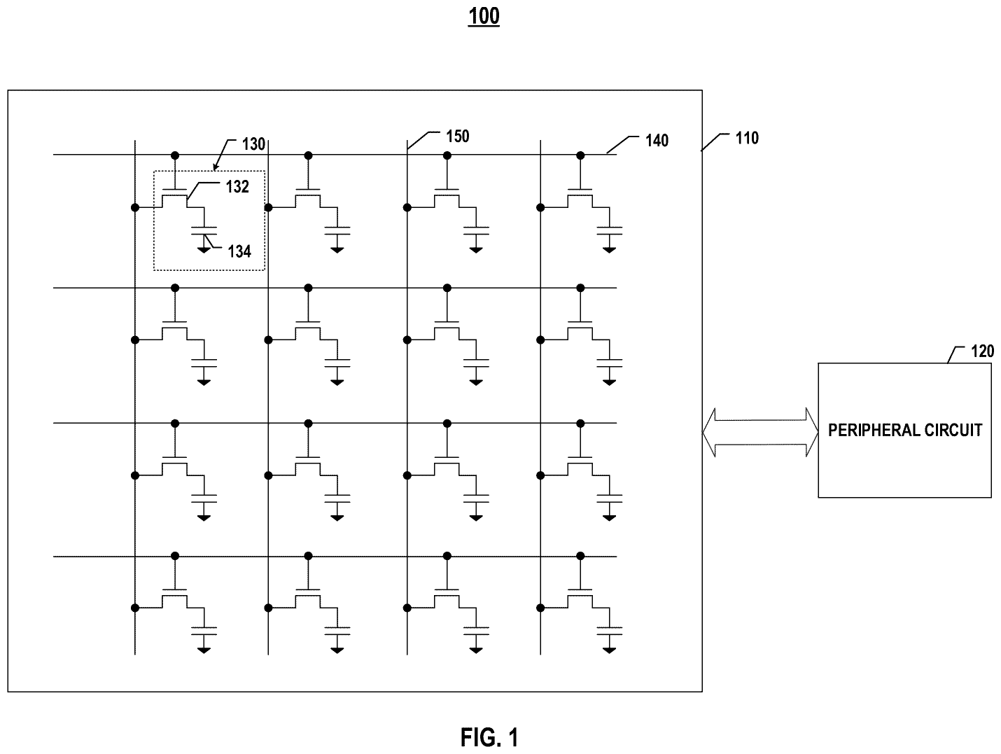

FIG. 1 illustrates a schematic diagram of a semiconductor device 100 including peripheral circuits and an array of memory cells each having a vertical transistor, according to some aspects of the present disclosure. Semiconductor device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder, a sense amplifier, a driver, an input/output (I/O) circuit, a charge pump, a voltage source or generator, a current or voltage reference, any portions of the functional circuits mentioned above, or any active or passive components of the circuit (e.g., transistors, diodes, resistors, or capacitors). Semiconductor device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

In some implementations, memory cell array 110 is a DRAM cell array, and storage unit 134 is a capacitor for storing charge as the binary information stored by the respective DRAM cell. As DRAM sizes continue to decrease, planner capacitors have been gradually replaced by stacked capacitors and trench capacitors to improve the density of DRAM cells. While stacked capacitors can only be formed after the fabrication of corresponding transistors, trench capacitors can be formed before the fabrication of corresponding transistors in DRAM devices, so that the subsequent transistors can avoid the high-temperature process for fabricating capacitors. Therefore, metal oxide and semiconductor materials, such as low-temperature polysilicon (LTPS) and indium gallium zinc oxide (IGZO), can be applied to DRAM devices employing trench capacitors to significantly reduce the leakage current and improve the performance of the DRAM devices. At the same time, the fabrication complexity and cost of DRAM devices employing trench capacitors are relatively high.

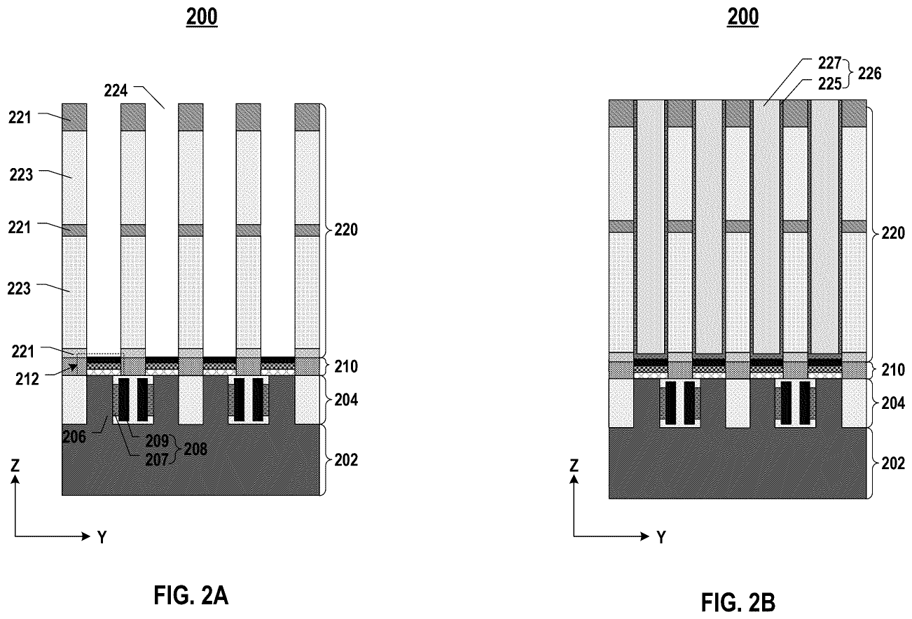

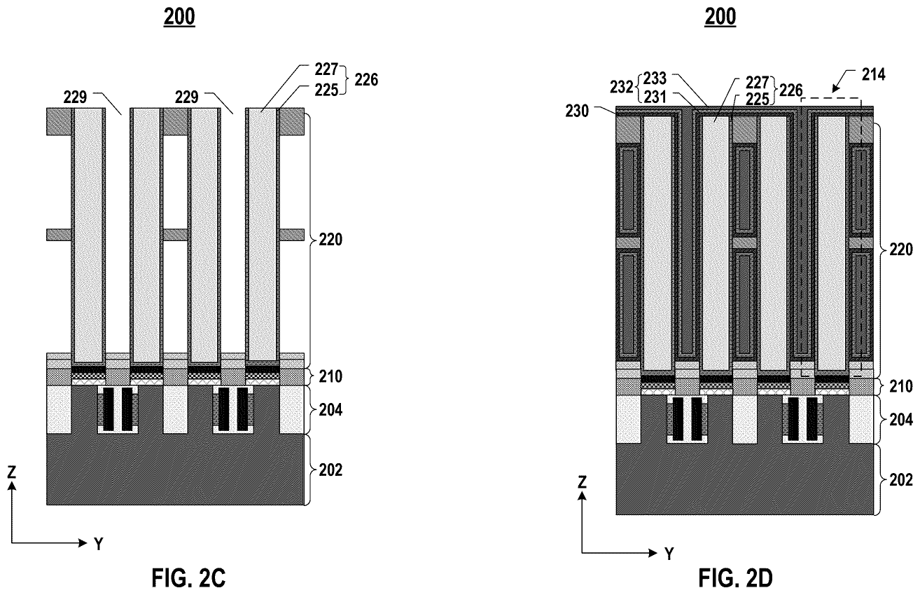

Referring to FIGS. 2A to 2D, a DRAM device 200 employing trench capacitors at certain stages of a fabricating process is shown. To illustrate the connecting structure and relationship between the trench capacitors and the corresponding transistors, in the present implementations, the transistors are formed before the fabrication process of the trench capacitors. It should be noted that the present implementations are illustrative, and the trench capacitors can be formed before the fabrication of corresponding transistors in some other implementations.

Referring to FIG. 2A, forming trench capacitors can include forming holes 224 in an isolation stack 220 above vertical transistors 204. Vertical transistors 204 can be designed to reduce the area occupied by each transistor, the coupling capacitance, as well as the interconnect routing complexity. As shown in FIG. 2A, vertical transistor 204 includes a semiconductor body 206 extending vertically (in the z-direction) above a substrate 202. That is, semiconductor body 206 can extend above the top surface of substrate 202, exposing not only the top surface of semiconductor body 206 but also one or more of its side surfaces, as shown in FIG. 2A. Semiconductor body 206 can be formed from the substrate (e.g., by etching or epitaxy) and thus, has the same semiconductor material (e.g., silicon crystalline silicon) as the substrate (e.g., a silicon substrate).

As shown in FIG. 2A, vertical transistor 204 can also include a gate structure 208 coupled with one or more sides of semiconductor body 206, i.e., at one or more lateral sides of the active region. In other words, the active region of vertical transistor 204, i.e., semiconductor body 206, can be at least partially surrounded by gate structure 208 in a lateral plane. The gate structure 208 can include a gate dielectric 207 over one or more sides of semiconductor body 206, e.g., coupled with four side surfaces of semiconductor body 206 as shown in FIG. 2A. Gate structure 208 can also include a gate electrode 209 over and coupled with gate dielectric 207. Gate dielectric 207 can include any suitable dielectric materials, such as silicon oxide, silicon nitride, silicon oxynitride, or high-k dielectrics. Gate electrode 209 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. Vertical transistor 204 can further include a pair of a source and a drain (S/D, dope regions, a.k.a., source electrode and drain electrode) formed at the two ends of semiconductor body 206 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). As a result, one or more channels (not shown) of vertical transistor 204 can be formed in semiconductor body 206 vertically between the source and drain when a gate voltage applied to the gate electrode of the gate structure exceeds the threshold voltage of vertical transistor 204. It is understood that vertical transistors 204 disclosed herein may include single-gate transistors, double-gate transistors, multiple-gate transistors, etc.

As shown in FIG. 2A, in some implementations, a source node contact (SNC) 212 is formed on one of the source or the drain of a corresponding transistor to decrease the contact resistance between vertical transistors 204 and corresponding trench capacitors. Adjacent SNCs 212 are isolated from each other by a dielectric layer 210 surrounding the SNCs 212. For example, SNC 212 may include multiple layers to couple with vertical transistor 204 and corresponding capacitor, respectively, and each layer can be one of TiN, TaN, carbon, polysilicon, metal, metal compounds, and silicide. For example, as shown in FIG. 2A, SNC 212 may include a first layer coupled with semiconductor body 206 directly, a second layer coupled with an electrode of capacitor directly, and a third layer sandwiched between the first and second layer. The first layer can be highly doped polysilicon to minimize the contact resistance with semiconductor body 206, the second layer can be metal material to reduce the contact resistance with the electrode of the capacitor, and the third layer can be metal nitride to reduce the contact resistance between the first and second layer. In this way, the contact resistance between vertical transistors 204 and the corresponding capacitors of the DRAM device can be reduced.

In some implementations, forming the trench capacitors can include forming an isolation stack 220 to cover SNCs 212. Isolation stack 220 has a relatively large height, which approximately equals the height of the trench capacitors to maximize the effective area of the electrodes of the trench capacitors. Therefore, to maintain mechanical stabilization during the fabrication process of capacitors, isolation stack 220 includes at least one sacrificial layer 223 and at least one mesh layer 221. Sacrificial layer 223 can be dielectric materials, such as silicon oxide. Mesh layer 221 includes larger dielectric materials with a Mohs scale larger than that of silicon oxide, which has a Mohs scale around six, so that the spacing between capacitors remains consistent, thereby preventing capacitor corruption. Without mesh layers 221, the capacitors would lean over and come into contact with adjacent capacitors. In some implementations, mesh layer 221 can be silicon nitride, silicon carbide, corundum, boron carbide, boron nitride, or any combination thereof. In some implementations, as the aspect ratio of the capacitors increases, two or more levels of mesh are required to ensure mechanical stability.

Referring to FIG. 2A, a plurality of holes 224 are formed in isolation stack 220, and each hole 224 penetrates isolation stack 220 to expose corresponding SNC 212. Then referring to FIG. 2B, a plurality of second electrodes 226 coupled with SNCs 212 are formed in the holes 224. In some implementations, each second electrode 226 includes multiple layers including different materials. For example, second electrode 226 includes a first layer 225 formed on the sidewall of hole 224 and a second layer 227 completely filling hole 224. First layer 225 and second layer 227 can include different conductive materials including, but not limited to, W, Co, Cu, Al, TiN, TaN, polysilicon, silicide, or any combination thereof. In some implementations, second electrode 226 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.)

In some implementations, referring to FIG. 2C, after forming second electrode 226, a plurality of openings 229 are formed on the at least one mesh layer 221, so that sacrificial layer 223 can be replaced by a dielectric layer and a first electrode in subsequent processes to form the capacitors 214. Sacrificial layer 223 can be removed by wet/dry etch, or any other suitable processes through the openings 229.

Referring to FIG. 2D, dielectric layer 230 and first electrode 232 are formed to fill the space occupied by sacrificial layer 223. Dielectric layer 230 includes dielectric materials, such as silicon oxide, silicon nitride, or high-k dielectrics including, but not limited to, Al₂O₃, HfO₂, Ta₂O₅, ZrO₂, TiO₂, or any combination thereof. Dielectric layer 230 of capacitor 214 may be formed by one or more thin film deposition processes (e.g., CVD, PVD, ALD, etc.) In some implementations, first electrode 232 can include conductive materials including, but not limited to, W, Co, Cu, Al, TiN, TaN, polysilicon, silicide, or any combination thereof. In some implementations, like second electrode 226, first electrode 232 may be a multiple-layer structure including a first layer 231 and a second layer 233. First layer 231 and second layer 233 include different conductive materials including, but not limited to, W, Co, Cu, Al, TiN, TaN, polysilicon, silicide, or any combination thereof. It should be noted that first electrode 232 and second electrode 233 can be a single-layer structure including only one conductive material and can also be a multiple-layer structure including more than two layers consisting of different conductive materials. The structure of the electrodes of capacitors 214 can be adjusted as needed based on the fabrication process and should not be explained as a limitation of the present disclosure.

As illustrated in FIGS. 2A to 2D, the complexity and cost of fabrication of a DRAM device employing trench capacitors are much higher than fabricating a DRAM device employing stacked capacitors because of the extra process for replacing sacrificial layer 223 with the dielectric layer and first electrode. Furthermore, an effective area between the electrodes of trench capacitors is smaller than that of stacked capacitors under the same aspect ratio due to the limitations of the trench process, which results in a smaller value of capacitors. With the decrease in sizes of the semiconductor device, the aspect ratio of the fabrication process is further reduced, making it impossible to form electrodes having a multiple-layer structure for trench capacitors.

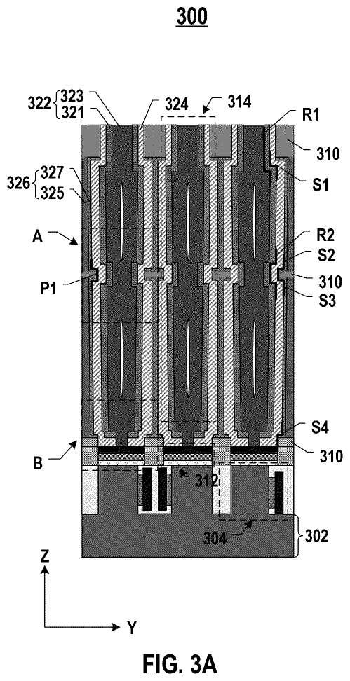

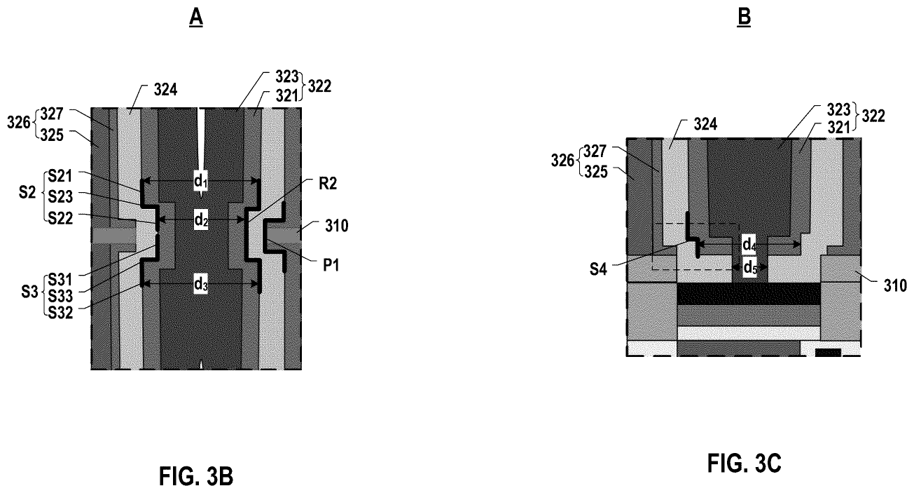

In some implementations, referring to FIG. 3A, a semiconductor device 300 including a plurality of transistors 304 and corresponding capacitors 314 is provided. The plurality of transistors 304 are formed vertically above a substrate 302. Each capacitor 314 is coupled with a corresponding transistor 304 through an SNC 312. Each capacitor 314 includes a first electrode 322, a dielectric layer 324, and a second electrode 326. First electrode 322 extends along the vertical direction (i.e., z-direction) and is coupled with corresponding transistor 304 through SNC 312.

In some implementations, first electrode 322 includes a first barrel layer 321 and a vertical core 323. Vertical core 323 may be, but not limited to, cylindrical, cubic, polygonal, and other shapes. First barrel layer 321 has the same shape as the dielectric layer and is coupled with dielectric layer 324 directly. Vertical core 323 is surrounded by first barrel layer 321 and fills in a cavity of first barrel layer 321. First barrel layer 321 can include materials including, but not limited to, Cr, W, Ti, TiW, Ni, Cr—Cu, TiN, or TiW, etc. First barrel layer 321 has good electrical conductivity, and also functions as a diffusion barrier to prevent conductive materials from entering into dielectric layer 324. Vertical core 323 can include conductive materials different from first barrel layer 321, such as W, Co, Cu, Al, polysilicon, silicide, or any combination thereof.

Similarly, second electrode 326 may include a second barrel layer 325 and a parcel layer 327. Second barrel layer 325 is coupled with dielectric layer 324 directly and has the same shape as dielectric layer 324. Parcel layer 327 is surrounded by second barrel layer 325. Second barrel layer 325 of second electrode 326 may include the same material as first barrel layer 321 of first electrode 322 and functions as a diffusion barrier. Second barrel layer 325 can include materials including, but not limited to, Cr, W, Ti, TiW, Ni, Cr—Cu, TiN, or TiW, etc. Second barrel layer 325 has good electrical conductivity, and functions as a diffusion barrier to prevent conductive materials from entering into dielectric layer 324. Parcel layer 327 can include conductive materials different from second barrel layer 325, such as W, Co, Cu, Al, polysilicon, silicide, or any combination thereof.

In some implementations, the height of first electrode 322 is larger than the height of second electrode 326 along the vertical direction. For example, the height of second electrode 326 approximately equals the distance from mesh layer 310 at the top to mesh layer 310 at the bottom, as shown in FIG. 3A, while the height of first electrode 322 is larger than the distance from mesh layer 310 at the top to mesh layer 310 at the bottom. The height difference arranged at the bottom portion of capacitor 314 is configured to isolate second electrode 326 from SNC 312 and transistor 304, thereby avoiding electrical malfunctions generated by the short current.

In some implementations, capacitors 314 may be, but not limited to, cylindrical, cubic, polygonal, and in any other suitable shapes. First electrode 322 is surrounded by dielectric layer 324 laterally, and dielectric layer 324 is surrounded by second electrode 326 laterally. The plurality of second electrodes 326 are coupled with a common electrode (not shown). Three mesh layers 310 are formed to surround the top portions, middle portions, and bottom portions of the capacitors 314 to keep the mechanical stabilization of capacitors 314. The number of layers of mesh layers 310 can be adjusted based on the height of capacitors 314, for example, with an increased height of the capacitors 314, four or five mesh layers 310 may be formed to protect capacitors 314 from corruption.

Dielectric layer 324 includes at least one step-shaped shift along the vertical direction, and each step-shaped shift corresponds to a diameter difference between a first diameter of the dielectric layer at a first side of the step-shaped shift and a second diameter of the dielectric layer at a second side of the step-shaped shift. For example, referring to FIG. 3A, dielectric layer 324 includes a first step-shaped shift S1 formed under mesh layer 310 at the top, a second step-shaped shift S2 and a third step-shaped shift S3 formed above and under mesh layer 310 in the middle, and a fourth step-shaped shift S4 formed above mesh layer 310 at the bottom. The bolded lines in FIG. 3A are used to assist in illustrating the scope and location of the corresponding step-shaped shift to facilitate description and understanding, and the corresponding structure of the bolded line in semiconductor device 300 makes no difference with adjacent regions. It is understood that the illustrative shapes and lines of semiconductor device 300 should not be read as limitations of the present disclosure. That is, the at least one step-shaped shift is formed near mesh layers 310. In some implementations, Dielectric layer 324 has one step-shaped shift formed corresponding to a mesh layer formed at the top portion or the bottom portion of capacitors 314, such as first step-shaped shift S1 and fourth step-shaped shift S4. In some implementations, dielectric layer 324 has two step-shaped shifts formed corresponding to a mesh layer formed at the middle portion or the bottom portion of capacitors 314, such as second step-shaped shift S2 and third step-shaped shift S3.

FIG. 3B and FIG. 3C illustrate enlarged views of region A and region B in FIG. 3A, respectively. Region A includes second step-shaped shift S2 and third step-shaped shift S3 formed above and under mesh layer 310 at the middle portion of a capacitor 314, and region B includes fourth step-shaped shift S4 formed above mesh layer 310 at the bottom portion of a capacitor 314. The bolded lines in FIGS. 3B and 3C are also used to assist in illustrating the scope and location of the corresponding step-shaped shift to facilitate description and should not be read as limitations of the present disclosure.

Referring to FIG. 3B, a mesh layer 310 at the middle portion of capacitor 314 protrudes around capacitor 314 and towards a center of capacitor 314. For example, mesh layer 310 may protrude towards a geometrical center of capacitor 314. Second step-shaped shift S2 and third step-shaped shift S3 continuously connect with each other and lift toward opposite directions along the vertical direction. For example, second step-shaped shift S2 includes a first step surface S21, a second step surface S22, and a lateral surface S23 connecting first step surface S21 and a second step surface S22. Third step-shaped shift S3 also includes a first step surface S31, a second step surface S32, and a lateral surface S33 connecting first step surface S31 and a second step surface S32. Referring to FIG. 3B, second step surface S22 of second step-shaped shift S2 and first step surface S31 of third step-shaped shift are connected with each other to form a common surface positioned corresponding to mesh layer 310 at the middle portion of dielectric layer 324. Along the vertical direction and extending from the top portion of capacitor 314 to the bottom portion of capacitor 314, second step surface S22 of second step-shaped shift S2 lifted up from corresponding first step surface S21, while second step surface S32 of third step-shaped shift S3 lifted down from corresponding first step surface S31, which is opposite to second step-shaped shift S2.

Further referring to FIG. 3B, dielectric layer 324 has a first inner diameter d₁ above mesh layer 310, a second inner diameter d₂ at mesh layer 310, and a third inner diameter d₃ below mesh layer 310. Taking second step-shaped shift S2 as an example, first inner diameter d₁ is the diameter of the first step surface of second step-shaped shift S2, which is greater than second inner diameter d₂, which is the diameter of the second step surface of second step-shaped shift S2. Similarly, the diameter of the first step surface of third step-shaped shift S3 (i.e., second inner diameter d₂ of dielectric layer 324) is smaller than the diameter of the second step surface of third step-shaped shift S3 (i.e., third inner diameter d₃ of dielectric layer 324).

Referring to FIG. 3C, as mesh layer 310 protrudes around capacitor 314 and towards the center of capacitor 314. For example, mesh layer 310 may protrude towards a geometrical center of capacitor 314. Dielectric layer 324 has a fourth step-shaped shift S4 formed above mesh layer 310 at the bottom. In this situation, dielectric layer 324 has an L-shaped cross section at the bottom portion of dielectric layer 324 due to the fourth step-shaped shift S4, as shown in FIG. 3C. Dielectric layer 324 has a fourth inner diameter d₄ above mesh layer 310 and a fifth inner diameter d₅ at mesh layer 310. As shown in FIG. 3C, a diameter of a first step surface of fourth step-shaped shift S4 (i.e., fourth inner diameter d₄ of dielectric layer 324) is greater than the diameter of a second step surface of fourth step-shaped shift S4 (i.e., fifth inner diameter d₅ of dielectric layer 324). In some implementations, the inner diameter of portions of dielectric layer 324 that are not surrounded by mesh layers 310 might be decreased gradually from the top of capacitor 314 to the bottom of capacitor 314. That is, fifth inner diameter d₅ might be smaller than third inner diameter d₃, and third inner diameter d₃ might be smaller than first inner diameter d₁.

In some implementations, referring to FIG. 3B, first electrode 322 includes a vertical body with at least one recess recessed towards the geometrical center of capacitor 314, such as a first recess RI and a second recess R2. The vertical body of first electrode 322 may be, but not limited to, cylindrical, cubic, polygonal, and in any other suitable shapes. The recess may be an annular-shaped recess around the vertical body. The at least one recess R1 corresponds to the at least one mesh layer 310 and is formed due to the existence of protruding mesh layer 310. In some implementations, each recess corresponds to a step-shaped shift of the dielectric layer. For example, first recess R1 corresponds to first step-shaped shift S1. As shown in FIG. 3B, a diameter of the recess is smaller than the diameter of the vertical body. For example, a diameter of second recess R2 (i.e., second inner diameter d₂ of dielectric layer 324) is smaller than the outer diameter of first electrode 322 (i.e., first inner diameter d₁ of dielectric layer 324). In some implementations, similar to dielectric layer 324, first electrode 322 has an L-shaped cross section at the bottom of first electrode 322.

In some implementations, referring to FIG. 3B, second electrode 326 includes a vertical cavity with at least one protrusion towards a geometrical center of the capacitor, such as a first protrusion P1 located corresponding to mesh layer 310 in a lateral plane. The vertical cavity may be, but not limited to, cylindrical, cubic, polygonal, and in any other suitable shapes. The at least one protrusion may be an annular-shaped protrusion around the vertical cavity. Each protrusion corresponds to a step-shaped shift of dielectric layer 324, and the diameter of the protrusion is smaller than the diameter of the vertical cavity. For example, a diameter of first protrusion P1 (i.e., second inner diameter d₂ of dielectric layer 324) is smaller than the inner diameter of second electrode 326 (i.e., first inner diameter d₁ of dielectric layer 324). In some implementations, similar to dielectric layer 324, second electrode 326 has an L-shaped cross section at the bottom of second electrode 326.

In some implementations, capacitors 314 are arranged in a grid array in which four adjacent capacitors 314 are located at four corners of a rectangle, respectively. Two second electrodes 326 of two capacitors 314 located at two adjacent corners of each rectangle in the grid array are in contact with each other, and a space between the four adjacent capacitors 314 located at four corners of a rectangle is filled by the second electrode of the four adjacent capacitors 314. It is understood that capacitors 314 in DRAM cells can be formed before or after the formation of transistors 304, and the fabrication sequence of capacitors 314 and transistors 304 should not be read as limitations of the present disclosure.

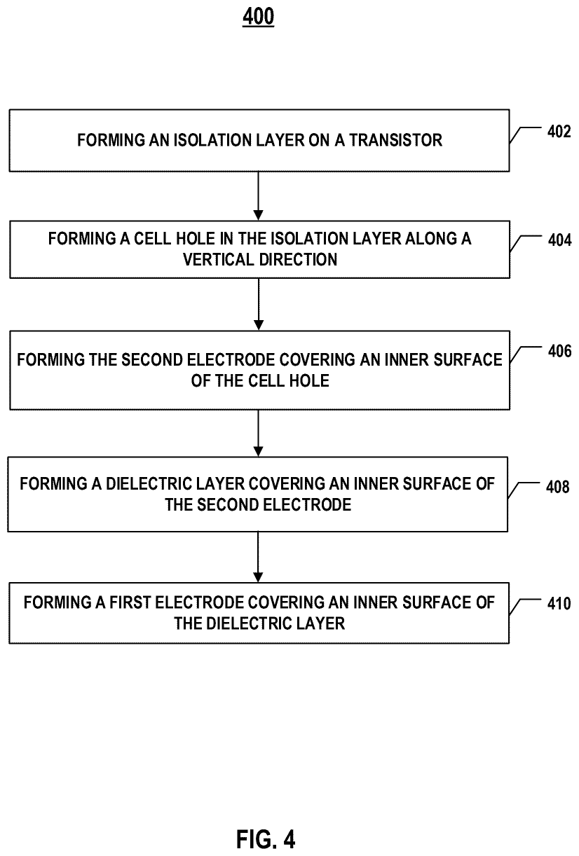

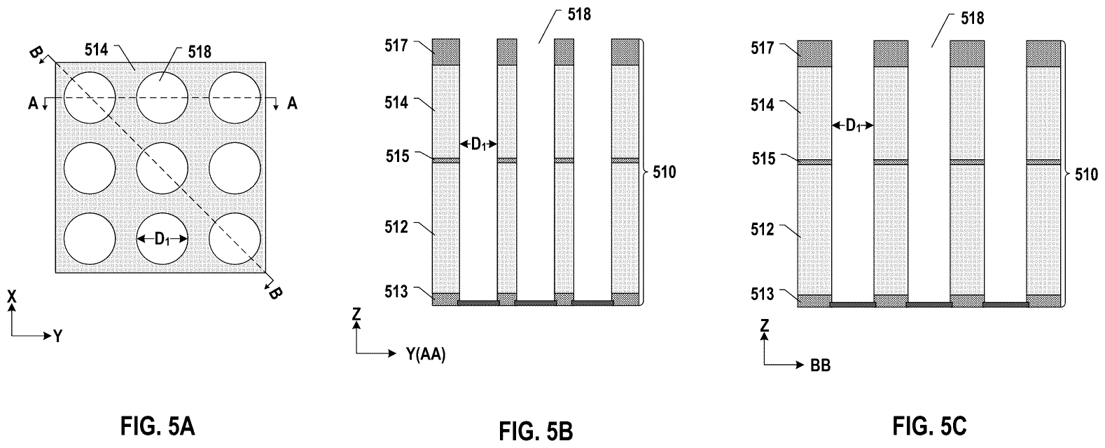

FIG. 4 illustrates a flowchart of a method 400 for forming a semiconductor device including trench capacitors 520 and corresponding transistors, according to some implementations of the present disclosure. FIGS. 5A-5C, 6A-6C, 7A-7C, 8A-8C, 9A-9C, 10A-10C, 11A-11C, and 12A-12C illustrate a fabrication process for forming the semiconductor device at certain fabricating stages of the method 400 shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously, or in a different order than shown in FIG. 4. In the present implementation, the transistors may be formed before or after the fabrication of trench capacitors 520. The sequence for fabricating the transistors and trench capacitors 520 can be arranged as needed and should not be explained as limitations of the present disclosure.

As shown in FIG. 4, method 400 can start at operation 402, in which an isolation layer 510 is formed for preparing the fabrication of trench capacitors 520. In some implementations that the transistors are formed after the fabrication of trench capacitors 520, isolation layer 510 is formed on a substrate. The substrate can include silicon (e.g., single crystalline silicon, c-Si), silicon germanium (SiGe), gallium arsenide (GaAs), germanium (Ge), silicon-on-insulator (SOI), or any other suitable materials. In some other implementations where the transistors are formed before the fabrication of trench capacitors 520, isolation layer 510 is formed on the transistors. In the present implementations, the structures on which isolation layer 510 is formed are omitted to case the description of the fabrication process of trench capacitors 520, as shown in FIG. 5B and FIG. 5C.

FIG. 5A illustrates a lateral cross-section of isolation layer 510, FIG. 5B is a vertical cross section of isolation layer 510 along the A-A direction (i.e., the Y-direction) and FIG. 5C is a vertical cross section of isolation layer 510 along the B-B direction (i.e., deviating 45° from the Y-direction). In some implementations, isolation layer 510 may be a multiple-layer structure including at least one mesh layer and at least one sacrificial layer stacked alternatively. For example, as shown in FIG. 5A, isolation layer 510 includes a first mesh layer 513 formed at the bottom of isolation layer 510, a first sacrificial layer 512 formed on first mesh layer 513, a second mesh layer 515 formed on first sacrificial layer 512, a second sacrificial layer 514 formed on second mesh layer 515, and a third mesh layer 517 formed on the top of isolation layer 510 and covering the second sacrificial layer 514. As shown in FIG. 5B and 5C, a top layer and a bottom layer of isolation layer 510 are third mesh layer 517 and first mesh layer 513, respectively, and first sacrificial layer 512 and second sacrificial layer 514 are sandwiched between the three mesh layers.

In some implementations, to avoid an aperture of a hole penetrating isolation layer 510 from decreasing as the increasing of the etching depth, first sacrificial layer 512 and second sacrificial layer 514 can include different materials with a different etching selectivity during a patterning process. For example, first sacrificial layer 512 at the lower portion of isolation layer 510 can be silicon oxide doped with boron, while second sacrificial layer 514 at the upper portion of isolation layer 510 can be silicon oxide doped with phosphorus. The three mesh layers may include dielectric materials with a Mohs scale larger than that of silicon oxide, which has a Mohs scale around six, such as silicon nitride, silicon carbide, corundum, boron carbide, boron nitride, or any combination thereof.

As shown in FIG. 4, method 400 then proceeds to operation 404, in which a plurality of holes 518 are formed in isolation layer 510 along the vertical direction, as shown in FIGS. 5A to 5C. In some implementations, holes 518 are arranged in a grid array in which four adjacent capacitors are located at four corners of a rectangle, respectively. The distance between two holes 518 on a diagonal of the rectangle is greater than the distance between two holes 518 on the same side of the rectangle, as shown in FIG. 5A. Holes 518 can be formed by a series of patterning processes including, but not limited to, photoetching, dry etching, wet etching, reactive ion etching, inductively coupled plasma etching, cleaning, etc. For example, dry etching processes, such as sputtering, can be used to form holes 518 with excellent anisotropic properties.

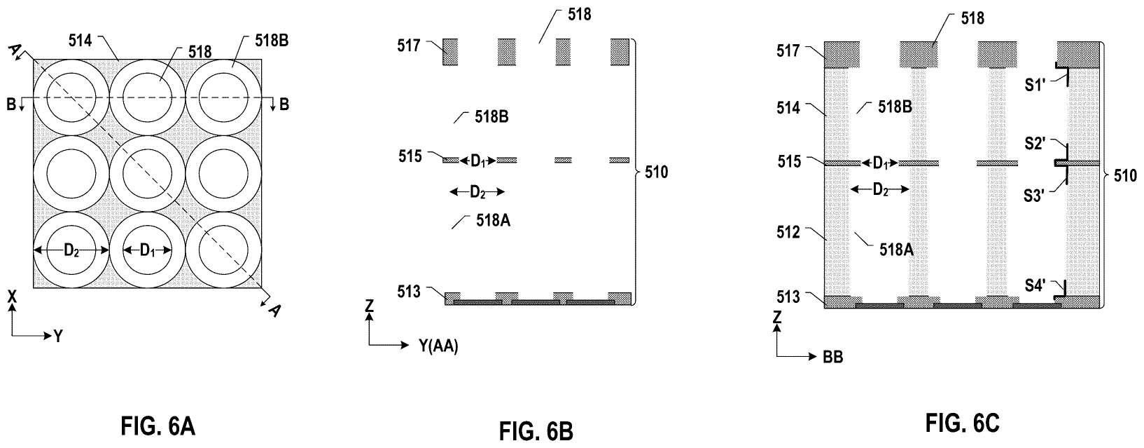

In some implementations, forming holes 518 further includes etching each sacrificial layer to form a corresponding recession along a lateral direction to laterally enlarge holes 518, as shown in FIG. 6A to FIG. 6C. For example, first sacrificial layer 512 and second sacrificial layer 514 are etched laterally so that they are recessed relative to the three mesh layers. In some implementations, an etching process with a high selectivity between silicon oxide and silicon nitride is applied to increase the diameter of hole 518 at the sacrificial layers from D₁ to D₂, while a diameter of hole 518 at the mesh layers remains D₁. For example, a wet etching using H₃PO₄ as an etchant can be used to remove portions of the sacrificial layers without damaging the mesh layers. As shown in FIGS. 6B and 6C, a first recession 518A is formed between first mesh layer 513 and second mesh layer 515, and a second recession 518B is formed between second mesh layer 515 and third mesh layer 517. An initial step-shaped shift is formed between each mesh layer and its adjacent sacrificial layer at the edge of each recession. For example, a first initial step-shaped shift S1′ is formed between third mesh layer 517 and second sacrificial layer 514 at an upper end of second recession 518B, and a second initial step-shaped shift S2′ is formed between second mesh layer 515 and second sacrificial layer 514 at a lower end of second recession 518B. A third initial step-shaped shift S3′ is formed between second mesh layer 515 and first sacrificial layer 512 at the upper end of first recession 518A, and a fourth initial step-shaped shift S4′ is formed between first mesh layer 513 and first sacrificial layer 512 at the lower end of first recession 518A. The number of the initial step-shaped shifts is positively proportional to the number of mesh layers of isolation layer 510. In some implementations, a mesh layer at the top or bottom of isolation layer 510 corresponds to one step-shaped shift. For example, first mesh layer 513 corresponds to fourth initial step-shaped shift S1′, and third mesh layer 517 corresponds to first initial step-shaped shift S4′. In some implementations, a mesh layer at the middle of isolation layer 510 corresponds to two step-shaped shifts. For example, second mesh layer 515 corresponds to second initial step-shaped S2′ and third initial step-shaped S3′.

FIG. 6B illustrates a lateral cross section along the A-A direction, as shown in FIG. 6B, the sidewall between two adjacent holes 518 along the A-A direction is penetrated with the formation of first and second recessions 518A and 518B so that holes 518 located at the same side of a rectangle are connected with each other. FIG. 6C illustrates a lateral cross section along the B-B direction, as shown in FIG. 6C, because the distance between two holes 518 on a diagonal of each rectangle is greater than the distance between two holes 518 on the same side of the rectangle, the sidewall between two adjacent holes 518 along the B-B direction is thinned, but not penetrated, while the sidewall between two adjacent holes 518 along the A-A direction are penetrated. Referring to FIG. 6A and FIG. 6C, a plurality of diamond pillars remains in the center of each rectangle of the grid array to support the three mesh layers.

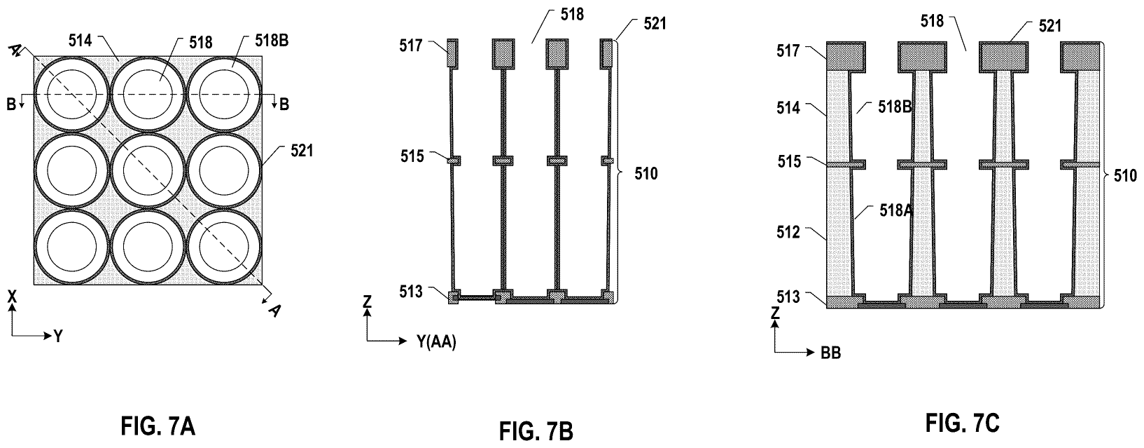

As shown in FIG. 4, method 400 then proceeds to operation 406, in which a second barrel layer 521 of a second electrode 522 is formed in each hole 518, and an inner surface of hole 518 is covered by second barrel layer 521, as shown in FIGS. 7A to 7C. In some implementations, second electrode 522 includes second barrel layer 521 and a parcel layer 523 surrounded by second barrel layer 521. FIG. 7A illustrates a lateral cross section of isolation layer 510 after a conductive film 521 is formed, FIG. 7B illustrates a vertical cross section along the A-A direction of FIG. 7A, and FIG. 7C illustrates a vertical cross section along the B-B direction of FIG. 7A.

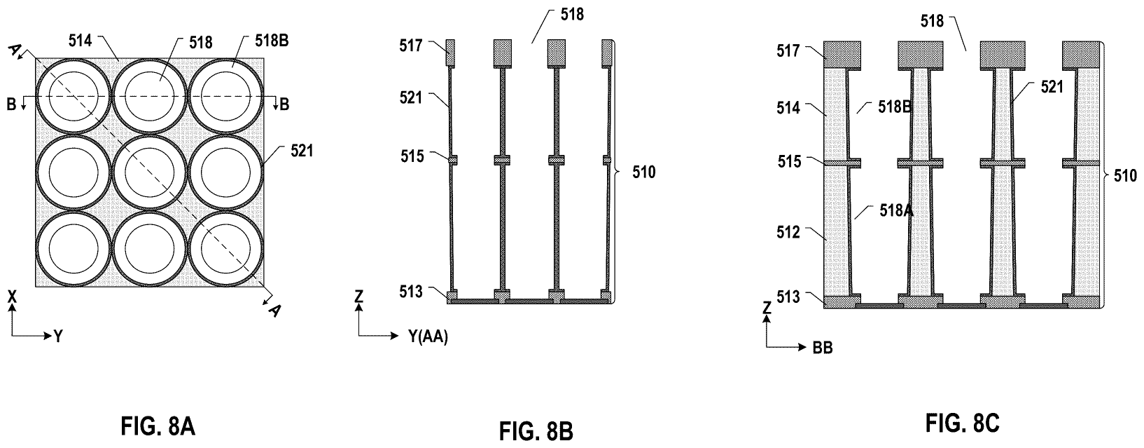

Second barrel layer 521 (also referred to herein as conductive film 521) can be materials including, but not limited to, Cr, W, Ti, TaW, Ni, Cr-Cu, TiN, or TiW, etc. Second barrel layer 521 has good electrical conductivity, and functions as a diffusion barrier to prevent conductive materials from entering into dielectric layer 524. As shown in FIG. 7A to FIG. 7C, conductive film 521 can be formed to cover the inner surface of each hole 518, including the vertical side surface of each sacrificial layer, the vertical side surface of each mesh layer, and the bottom surface of each hole 518. Conductive film 521 can be formed by fabricating processes including thin film deposition processes (e.g., CVD, PVD, ALD, etc.) In some implementations, portions of conductive film 521 covering the surfaces of the three mesh layers can be removed to expose the vertical side surfaces of each mesh layer, as shown in FIG. 8B and FIG. 8C. FIG. 8A illustrates a lateral cross section of isolation layer 510 after second barrel layer 521 is formed, FIG. 8B illustrates a vertical cross section along the A-A direction of FIG. 8A, and FIG. 8C illustrates a vertical cross section along the B-B direction of FIG. 8A. In such implementations, an edge of second barrel layer 521 may not extend beyond first mesh layer 513, so that second barrel layer 521 can be isolated from a corresponding transistor by first mesh layer 513 to avoid the risk of short current. As shown in FIG. 8A to FIG. 8C, second barrel layer 521 covers the side surfaces of first sacrificial layer 512 and second sacrificial layer 514. The second barrel layer 521 can be formed by a series of patterning processes (e.g., photoetching, dry etching, wet etching, cleaning, chemical mechanical polishing (CMP), etc.)

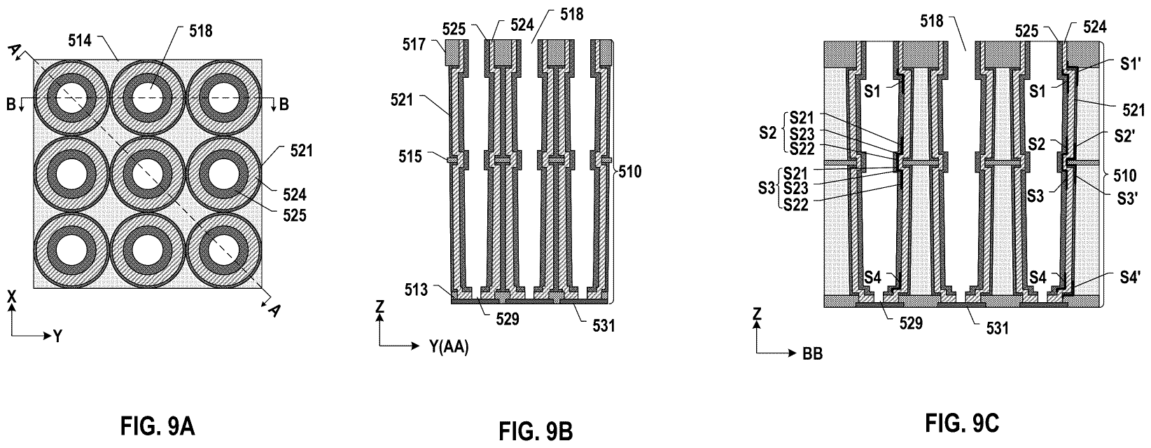

As shown in FIG. 4, method 400 proceeds to operation 408, in which a dielectric layer 524 is formed to cover the inner surface of second barrel layer 521. Method 400 then proceeds to operation 410, in which a first electrode 526 laterally surrounded by dielectric layer 524 is formed, as shown in FIGS. 9A-9C, 10A-10C, 11A-11C, and 12A-12C. First electrode 526 is coupled with a corresponding transistor (not shown). In some implementations, first electrode 526 includes a first barrel layer 525 and a vertical core 527. Vertical core 527 may be, but not limited to, cylindrical, cubic, polygonal, and other shapes. First barrel layer 525 is formed on the inner surface of dielectric layer 524 to partially fill hole 518, vertical core 527 is surrounded by first barrel layer 525 and fully fills hole 518.

Referring to FIG. 9A to FIG. 9C, FIG. 9A illustrates a lateral cross section of isolation layer 510 after dielectric layer 524 and first barrel layer 525 are formed, FIG. 9B illustrates a vertical cross section along the A-A direction of FIG. 9A, and FIG. 9C illustrates a vertical cross section along the B-B direction of FIG. 9A. Dielectric layer 524 includes dielectric materials, such as silicon oxide, silicon nitride, or high-k dielectrics including, but not limited to, Al₂O₃, HfO₂, Ta₂O₅, ZrO₂, TiO₂, or any combination thereof. First barrel layer 525 is coupled to dielectric layer 524 directly. In some implementations, first barrel layer 525 can include materials including, but not limited to, Cr, W, Ti, TaW, Ni, Cr-Cu, TiN, or TiW, etc. First barrel layer 525 has good electrical conductivity, and functions as a diffusion barrier to prevent conductive materials from entering into dielectric layer 524. Dielectric layer 524 and first barrel layer 525 can be formed by a series of fabricating processes including thin film deposition processes (e.g., CVD, PVD, ALD, etc.) and patterning processes (e.g., photoetching, dry etching, wet etching, cleaning, chemical mechanical polishing (CMP), etc.)

As shown in FIG. 9C, dielectric layer 524 includes at least one step-shaped shift corresponding to the at least one initial step-shaped shift formed in isolation layer 510, because dielectric layer 524 has the same shape as the inner surface of hole 518. For example, dielectric layer 524 includes first step-shaped shift S1 formed at the top portion of isolation layer 510, second step-shaped shift S2 and third step-shaped shift S3 formed at the middle portion of isolation layer 510, and fourth step-shaped shift S4 formed at the bottom of isolation layer 510. First step-shaped shift S1 corresponds to first initial step-shaped shift S1′, second step-shaped shift S2 corresponds to second initial step-shaped shift S2′, third step-shaped shift S3 corresponds to third initial step-shaped shift S3′, and fourth step-shaped shift S4 corresponds to fourth initial step-shaped shift S4′. The number of the step-shaped shifts is positively proportional to the number of mesh layers of isolation layer 510. In some implementations, a mesh layer at the top or bottom of isolation layer 510 corresponds to one step-shaped shift, such as S1 and S4. Referring to FIG. 9C, dielectric layer 524 has an L-shaped cross section at the bottom of dielectric layer 524, because the fourth step-shaped shift S4 is formed at the bottom of dielectric layer 524 along the vertical direction. In some implementations, a mesh layer in the middle of isolation layer 510 corresponds to two step-shaped shifts that are continuously connected with each other, such as S2 and S3.

Referring to FIG. 9C, in some implementations, along the vertical direction and extending from the top portion of isolation layer 510 to the bottom portion of isolation layer 510, second step-shaped shift S2 lifted towards a direction opposite to the direction in which third step-shaped shift S3 lifted towards. For example, second step-shaped shift S2 includes a first step surface S21, a second step surface S22, and a lateral surface S23 connecting first step surface S21 and a second step surface S22. Third step-shaped shift S3 also includes a first step surface S31, a second step surface S32, and a lateral surface S33 connecting first step surface S31 and a second step surface S32. Referring to FIG. 3B, second step surface S22 of second step-shaped shift S2 and first step surface S31 of third step-shaped shift are connected with each other to form a common surface positioned corresponding to mesh layer 310 at the middle portion of dielectric layer 324. Along the vertical direction and extending from the top portion of capacitor 314 to the bottom portion of capacitor 314, second step surface S22 of second step-shaped shift S2 lifted up from corresponding first step surface S21, while second step surface S32 of third step-shaped shift S3 lifted down from corresponding first step surface S31, which is opposite to second step-shaped shift S2.

In some implementations, the corresponding transistors are formed before the fabrication of capacitors 520. That is, capacitors 520 are formed on the transistors, and each first electrode 526 is coupled to the source end of the corresponding transistor at the bottom of the corresponding capacitor 520. In such implementations, a through hole 529 is formed on the bottom of each hole 518 to punch through dielectric layer 524 and first barrel layer 525, so that first electrode 526 can be coupled with the corresponding transistor through an SNC 531, as shown in FIG. 9B and FIG. 9C. In some implementations, through hole 529 is formed after the formation of dielectric layer 524 and before the formation of first barrel layer 525. In such implementations, the bottom of dielectric layer 524 can be punched through to form through hole 529, so that first electrode 526 can be coupled with corresponding transistors. In some other implementations, the corresponding transistors are formed after the fabrication of capacitors 520. That is, capacitors 520 are formed below the transistors, each first electrode 526 can be coupled to the source end of a corresponding transistor at the top of a corresponding capacitor 520. In these implementations, the formation of through holes 529 can be omitted. As shown in FIG. 9A to FIG. 9C, after the formation of dielectric layer 524 and first barrel layer 525, hole 518 is partially filled.

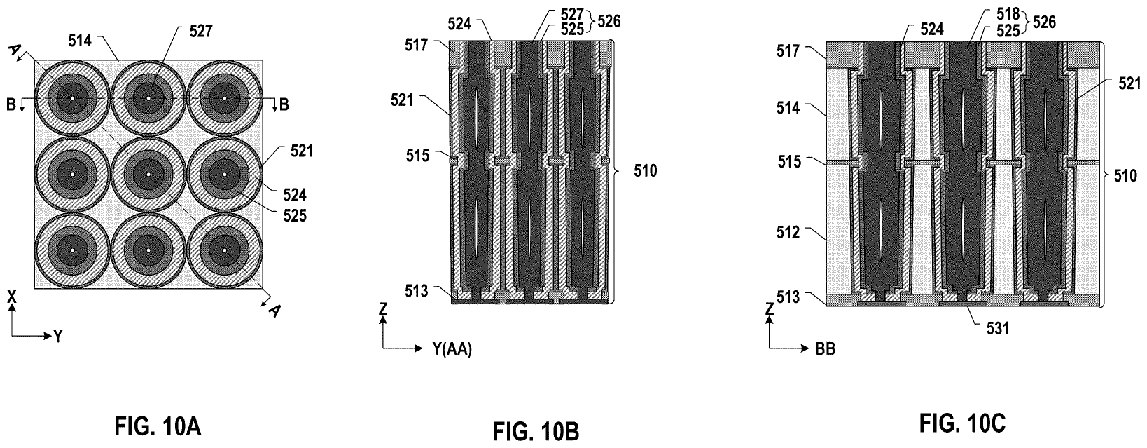

In some implementations, referring to FIG. 10A to FIG. 10C, the vertical core 527 is formed to fill hole 518. FIG. 10A illustrates a lateral cross section of isolation layer 510 after vertical core 527 is formed, FIG. 10B illustrates a vertical cross section along the A-A direction of FIG. 10A, and FIG. 10C illustrates a vertical cross section along the B-B direction of FIG. 10A. Vertical core 527 can include conductive materials different from that of first barrel layer 525, such as W, Co, Cu, Al, polysilicon, silicide, or any combination thereof. In some implementations, vertical core 527 may include more than two layers including different materials, respectively, to achieve higher capacitance. With the decreasing aspect ratio of hole 518, it becomes more difficult to form a multi-layer vertical core 527. In some implementations, vertical core 527 can be omitted such that first electrode 526 includes the first barrel layer 525 only. The structure of first electrode 526 varies based on the size of the semiconductor device and its fabrication process. It should be noted that the structure of first electrode 526 should not be read as limitations of the present disclosure.

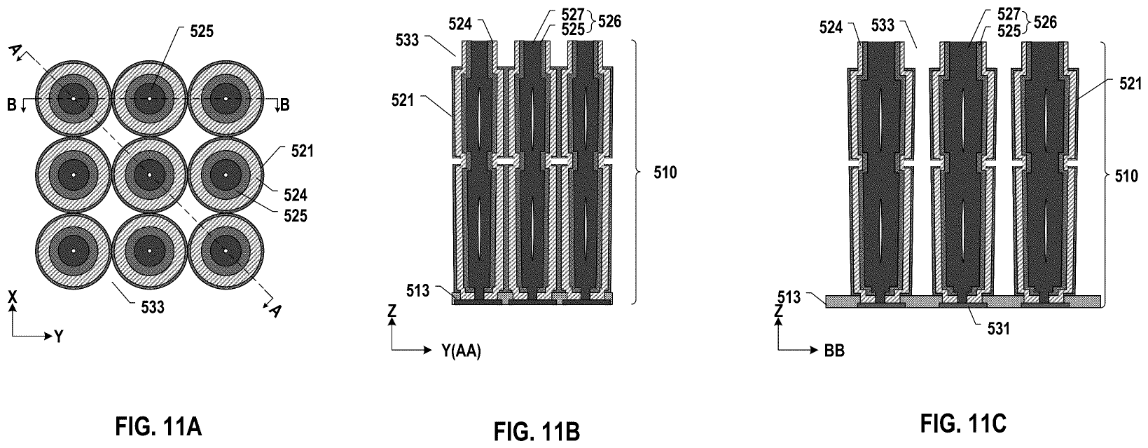

In some implementations, referring to FIG. 11A to FIG. 11C, at least part of isolation layer 510 is removed to form a space 533. FIG. 11A illustrates a lateral cross section of isolation layer 510 after sacrificial layers being removed, FIG. 11B illustrates a vertical cross section along the A-A direction of FIG. 11A, and FIG. 11C illustrates a vertical cross section along the B-B direction of FIG. 11A.In some implementations, capacitors 520 are formed after the fabrication of the corresponding transistors, as shown in FIG. 11B and 11C, then third mesh layer 517, second sacrificial layer 514, second mesh layer 515, and first sacrificial layer 512 are removed, while first mesh layer 513 remains to isolate the second electrode 522 from the corresponding transistors. In some other implementations, capacitors 520 are formed before the fabrication of corresponding transistors, isolation layer 510 can be removed entirely. The removal of isolation layer 510 can be accomplished by a series of patterning processes including, but not limited to, photoetching, dry etching, wet etching, reactive ion etching, inductively coupled plasma etching, cleaning, etc.

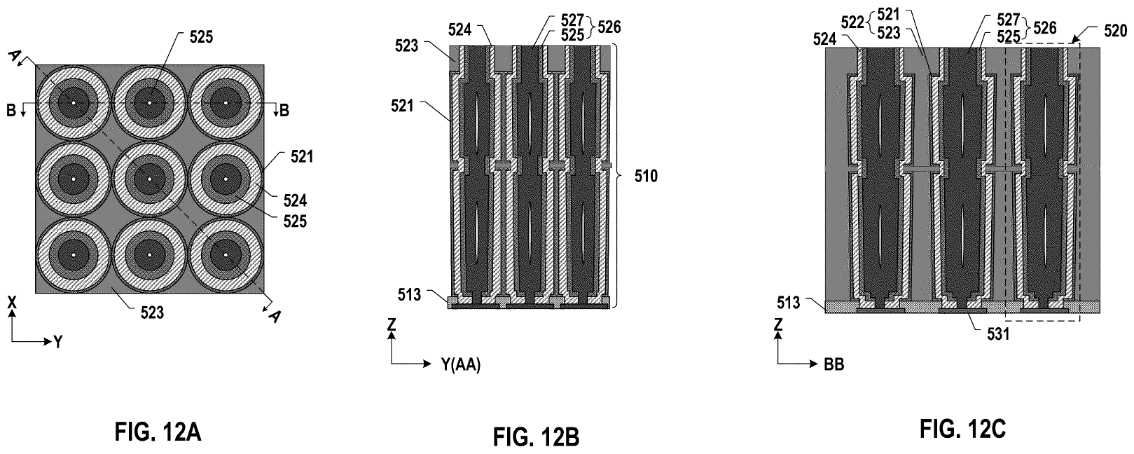

In some implementations, referring to FIG. 12A to FIG. 12C, space 533 is filled by conductive materials to form parcel layer 523 of second electrode 522. FIG. 12A illustrates a lateral cross section of isolation layer 510 after space 533 is filled, FIG. 12B illustrates a vertical cross section along the A-A direction of FIG. 12A, and FIG. 12C illustrates a vertical cross section along the B-B direction of FIG. 12A.That is, isolation layer 510 is replaced by parcel layer 523. Parcel layer 523 fills the space outside second barrel layers 521 of the plurality of second electrodes 522, and functions as a common electrode, which is configured to be connected to a reference voltage (e.g., the ground voltage) during the operation. Parcel layer 523 can include conductive materials different from second barrel layer 521, such as W, Co, Cu, Al, polysilicon, silicide, or any combination thereof.

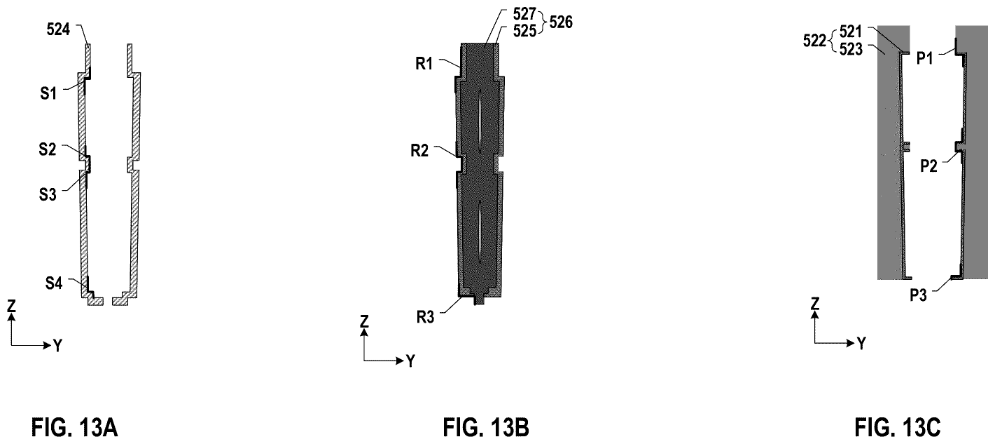

Referring to FIG. 13A to FIG. 13C, the structures of components of capacitor 520 formed by method 400 are illustrated in detail. FIG. 13A illustrates a vertical cross section of dielectric layer 524 of capacitor 520, FIG. 13B illustrates a vertical cross section of first electrode 526 of capacitor 520, and FIG. 13C illustrates a vertical cross section of second electrode 522 of capacitor 520. The bolded lines in FIGS. 13A-13C are used to assist in illustrating the scope and location of the corresponding structure (i.e., the step-shaped shifts, the recesses, and the protrusion) to facilitate description and understanding, and the corresponding structure of the bolded line makes no difference with adjacent regions. It is understood that the illustrative shapes and lines in FIGS. 13A-13C should not be read as limitations of the present disclosure.

Referring to FIG. 13A, dielectric layer 524 has a barrel-shaped body with four step-shaped shifts. For example, in some implementations, dielectric layer 524 includes first step-shaped shift S1 formed at the top portion of capacitor 520, second step-shaped shift S2 and third step-shaped shift S3 formed at the middle portion of capacitor 520, and fourth step-shaped shift S4 formed at the bottom of capacitor 520. The four step-shaped shifts are formed because that the sacrificial layers of isolation layer 510 are further etched to enlarge holes 518 during the fabrication process of capacitors 520. The side surface of dielectric layer 524 can be straight without any shift in the vertical direction if holes 518 are not enlarged.

Referring to FIG. 13B, first electrode 526 has a vertical-shaped body with three recesses relative to the vertical-shaped body. For example, in some implementations, dielectric layer 524 includes a first recess R1 formed at the top portion of capacitor 520, a second recess R2 formed at the middle portion of capacitor 520, and a third recess R3 formed at the bottom portion of capacitor 520. The three recesses correspond to the three mesh layers of isolation layer 510, and each recess corresponds to at least one step-shaped shift of dielectric layer 524. The recesses are formed because the sacrificial layers of isolation layer 510 are further etched to enlarge holes 518 during the fabrication process of capacitors 520. The side surface of first electrode 526 can be straight without any recess in the vertical direction if holes 518 are not enlarged.

Referring to FIG. 13C, second electrode 522 has a barrel-shaped body with three protrusions extending towards a geometrical center of capacitor 520. For example, in some implementations, second electrode 522 includes a first protrusion PI formed at the top portion of capacitor 520, a second protrusion P2 formed at the middle portion of capacitor 520, and a third protrusion P3 formed at the bottom portion of capacitor 520. The three protrusions correspond to the three mesh layers of isolation layer 510, and each protrusion corresponds to at least one step-shaped shift of dielectric layer 524. The protrusions are formed because the sacrificial layers of isolation layer 510 are further etched to enlarge holes 518 during the fabrication process of capacitors 520. The side surface of second electrode 522 can be straight without any protrusion in the vertical direction if holes 518 are not enlarged.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor device, comprising transistors and capacitors coupled with the transistors, respectively, wherein each capacitor comprises:
a first electrode extending along a vertical direction and coupled with a corresponding transistor;
a dielectric layer laterally surrounding the first electrode; and
a second electrode laterally surrounding the dielectric layer; wherein
the dielectric layer comprises:
at least one step-shaped shift along the vertical direction; and
a diameter difference between a first diameter of the dielectric layer at a first side of the step-shaped shift and a second diameter of the dielectric layer at a second side of the step-shaped shift.

2. The semiconductor device of claim 1, wherein the dielectric layer comprises:
a first step-shaped shift and a second step-shaped shift continuously connected with each other and lifted toward opposite directions along the vertical direction.

3. The semiconductor device of claim 2, wherein the first step-shaped shift and the second step-shaped shift share a common step surface positioned at a middle portion of the dielectric layer along the vertical direction.

4. The semiconductor device of claim 1, wherein the dielectric layer comprises:
a third step-shaped shift at a bottom of the dielectric layer along the vertical direction, and the dielectric layer has an L-shaped cross section at the bottom of the dielectric layer.

5. The semiconductor device of claim 1, wherein
the first electrode comprises a vertical body with at least one recess around the vertical body;
the at least one recess corresponds to the at least one step-shaped shift of the dielectric layer; and
a diameter of the recess is smaller than a diameter of the vertical body.

6. The semiconductor device of claim 1, wherein
the first electrode has an L-shaped cross section at a bottom of the first electrode; or
the second electrode has an L-shaped cross section at a bottom of the second electrode.

7. The semiconductor device of claim 1, the first electrode comprising:
a first barrel layer having a same shape with the dielectric layer; and
a vertical core filled in a cavity of the first barrel layer, wherein
a material of the first barrel layer is different from a material of the vertical core.

8. The semiconductor device of claim 1, wherein
the second electrode comprises a vertical cavity with at least one protrusion around the vertical cavity;
the at least one protrusion corresponds to the at least one step-shaped shift of the dielectric layer; and
a diameter of the protrusion is smaller than a diameter of the vertical cavity.

9. The semiconductor device of claim 1, the second electrode comprising:
a second barrel layer having a same shape as the dielectric layer; and
a parcel layer surrounding the second barrel layer; wherein
a material of the second barrel layer is different from a material of the parcel layer.

10. The semiconductor device of claim 1, wherein the capacitors are arranged in a grid array in which four adjacent capacitors are located at four corners of a rectangle, respectively.

11. The semiconductor device of claim 10, wherein
two second electrodes of two capacitors located at two adjacent corners of each rectangle in the grid array are in contact with each other; and
a space between the four adjacent capacitors located at four corners of a rectangle is filled by the second electrode of the four adjacent capacitors.

12. A method for forming a semiconductor device, comprising:
forming a second electrode of a capacitor along a vertical direction;
forming a dielectric layer of the capacitor laterally surrounded by the second electrode;
forming at least one step-shaped shift on the dielectric layer along the vertical direction, wherein a first diameter of the dielectric layer at a first side of the step-shaped shift is different with a second diameter of the dielectric layer at a second side of the step-shaped shift; and
forming a first electrode laterally surrounded by the dielectric layer.

13. The method of claim 12, wherein forming the second electrode comprises:
forming an isolation layer on a transistor;
forming a hole in the isolation layer along a vertical direction; and
forming the second electrode covering an inner surface of the hole.

14. The method of claim 13, wherein the isolation layer comprises:
a multiple-layer structure comprising at least one mesh layer and at least one sacrificial layer stacked alternatively; and
a top layer and a bottom layer of the multiple-layer structure are mesh layers.

15. The method of claim 14, forming the hole in the isolation layer comprising:
etching each sacrificial layer to form a corresponding recession along a lateral direction; wherein
an adjacent mesh layer protrudes into the hole with respect to the sacrificial layer; and
at least one initial step-shaped shift is formed between a mesh layer and an adjacent sacrificial layer at an edge of each recession.

16. The method of claim 15, wherein forming the second electrode in the hole comprises:
forming a second barrel layer covering a side surface of the hole; and
etching part of the second barrel layer to expose a vertical surface of each mesh layer and a bottom of the hole.

17. The method of claim 16, wherein forming the dielectric layer and forming the at least one step-shaped shift on the dielectric layer comprises:
forming the dielectric layer covering an inner surface of the second barrel layer, the vertical surface of each mesh layer, and the bottom of the hole; and
forming at least one step-shaped shift corresponding to the at least one initial step-shaped shift.

18. The method of claim 17, wherein forming the first electrode comprises:
forming a first barrel layer covering the dielectric layer;
forming a through hole penetrating the dielectric layer and the first barrel layer on the bottom of the hole to expose a transistor under the capacitor, a diameter of the through hole is smaller than an inner diameter of the first barrel layer; and
forming a vertical core filled in a cavity of the first barrel layer and the through hole to couple the first electrode with a transistor, a material of the vertical core is different from a material of the first barrel layer.

19. The method of claim 18, wherein the semiconductor device comprises a plurality of capacitors, and the method further comprises:
forming a plurality of transistors corresponding to the plurality of capacitors; and
the capacitors are arranged in a grid array in which four adjacent capacitors are located at four corners of a rectangle, respectively.

20. A semiconductor device, comprising:
a plurality of capacitors arranged in a grid array in which four adjacent capacitors are located at four corners of a rectangle, respectively;
wherein each of the capacitor comprises:
a first electrode extending along a vertical direction and coupled with a corresponding transistor;
a dielectric layer laterally surrounding the first electrode; and
a second electrode laterally surrounding the dielectric layer; and
wherein the dielectric layer of each electrode has an L-shaped cross section at a bottom of the dielectric layer.
